(19) United States
(12) Patent Application Publication
(10) Pub. No.: US 2025/0133879 A1
(43) Pub. Date: Apr. 24, 2025

(54) LAYERING METHOD FOR FLUORESCENT MATERIALS

(71) Applicant: Najing Technology Corporation Ltd., Zhejiang (CN)

(72) Inventors: Yukai Su, Zhejiang (CN); Baozhong Hu, Zhejiang (CN); Jianxing Yu, Zhejiang (CN); Jun Bai, Zhejiang (CN); Jun Zhou, Zhejiang (CN)

(73) Assignee: Najing Technology Corporation Ltd., Zhejiang (CN)

(21) Appl. No.: 18/921,926

(22) Filed: Oct. 21, 2024

Related U.S. Application Data
(60) Provisional application No. 63/592,413, filed on Oct. 23, 2023.

(51) Int. Cl. H01L 33/50; C09J 7/38; C09J 11/04; C09K 11/02; C09K 11/61; C09K 11/88

(52) U.S. Cl. CPC H10H 20/8513; C09J 7/38; C09J 11/04; C09K 11/02; C09K 11/617; C09K 11/883; C09J 2301/208; C09J 2301/408; H10H 20/0361

(57) ABSTRACT

A method for making a layered structure includes mixing a red fluorescent material and a green fluorescent material with a curable resin to produce an adhesive mixture, dispensing the adhesive mixture onto a substrate, centrifuging the adhesive mixture such that the red fluorescent material and the green fluorescent material separate to form a layered structure, and curing the layered structure onto the substrate. Another method includes applying an external field to the adhesive mixture such that the red fluorescent material and the green fluorescent material separate to form a layered structure. Yet another method includes phase separating the adhesive mixture such that the red fluorescent material and green fluorescent material separate to form a layered structure.

### BACKGROUND

In the application of white light light-emitting devices (LEDs), one approach is to mix a red fluorescent material and a green fluorescent material to form a fluorescent material mixture. Then, a blue light emitting chip is used as a light source to excite the fluorescent material mixture. Rationally setting a mixing ratio and concentration relationship between the red light fluorescent material and the green light fluorescent material in the fluorescent material mixture is critical, as the finally transmitted light is required to be white light.

The fluorescent material mixture formed by mixing the red fluorescent material and the green fluorescent material has a problem of self-absorption of light, resulting in low light emitting efficiency of the fluorescent material mixture. Accordingly, there exists a need for methods of fabricating these types of LEDS that improve the excitation efficiency of the fluorescent material, effectively improving the luminous efficiency of the light-emitting device.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method for making a layered structure. The method includes mixing a red fluorescent material and a green fluorescent material with a curable resin to produce an adhesive mixture, dispensing the adhesive mixture onto a substrate, centrifuging the adhesive mixture such that the red fluorescent material and the green fluorescent material separate to form a layered structure, and curing the layered structure onto the substrate.

In another aspect, embodiments disclosed herein relate to a method for making a layered structure that includes mixing a red fluorescent material and a green fluorescent material with a curable resin to produce an adhesive mixture, dispensing the adhesive mixture onto a substrate, applying an external field to the adhesive mixture such that the red fluorescent material and the green fluorescent material separate to form a layered structure, and curing the layered structure onto the substrate.

In yet another aspect, embodiments disclosed herein relate to a method for making a layered structure that includes mixing a red fluorescent material and a green fluorescent material with a curable resin to produce an adhesive mixture, dispensing the adhesive mixture onto a substrate, phase separating the adhesive mixture such that the red fluorescent material and green fluorescent material separate to form a layered structure, and curing the layered structure onto the substrate.

In another aspect embodiments disclosed herein relate to layered structures formed from the disclosed methods.

Other aspects and advantages of the claimed subject matter will be apparent from the following description and the appended claims.

### BRIEF DESCRIPTION OF DRAWINGS

FIG. 1 is a diagram of a layered structure according to one or more embodiments.

FIG. 2A is an example of an LED structure according to one or more embodiments.

FIG. 2B is an example of a layered structure according to one or more embodiments.

### DETAILED DESCRIPTION

White LEDs may be made from a mixture of red and green fluorescent materials that are excited with a blue light to produce white light. It can be advantageous to layer the red and green structures such that the red fluorescent material is closer to the blue light than the green fluorescent material in order to minimize self-absorption of light in a mixture of red and green fluorescent materials. Conventional methods for fabricating such devices include preparing two separate resin mixtures, one including a red fluorescent material and one including a green fluorescent material, and then separately layering these materials onto a substrate. This methodology can be cumbersome, with two separate steps of dispensing a resin mixture, where each mixture must also be cured. In contrast, the methods described herein include preparing one mixture that includes both red and green fluorescent materials and then either chemically or physically separating the materials to form a layered structure. These methods can avoid multiple dispensing and curing steps, while also providing an LED with high light efficiency. The methods also provide layered structures useful for applications in LEDs.

In one aspect, embodiments disclosed herein relate to methods of preparing a light conversion LED package, which include mixing at least two fluorescent materials and a curable resin to obtain an adhesive mixture and dispensing in one step the adhesive mixture on the LED chip. The fluorescent materials may then be separated into different layers through chemical or physical means. The fluorescent material with a long emission peak wavelength may be closer to the substrate than the fluorescent material with a short emission peak wavelength. The two fluorescent materials are thus located in different layers. Once separated into different layers, the structure may be cured to obtain the light conversion LED package.

In the present disclosure, reference is made to red and green fluorescent materials. Red fluorescent materials emit photons having a wavelength in the red portion of the visible spectrum and green fluorescent materials emit photons having a wavelength in the green portion of the visible spectrum. Red fluorescent materials may also be referred to as “long wavelength” materials while green fluorescent materials may be referred to as “short wavelength” materials. The terms may be used interchangeably.

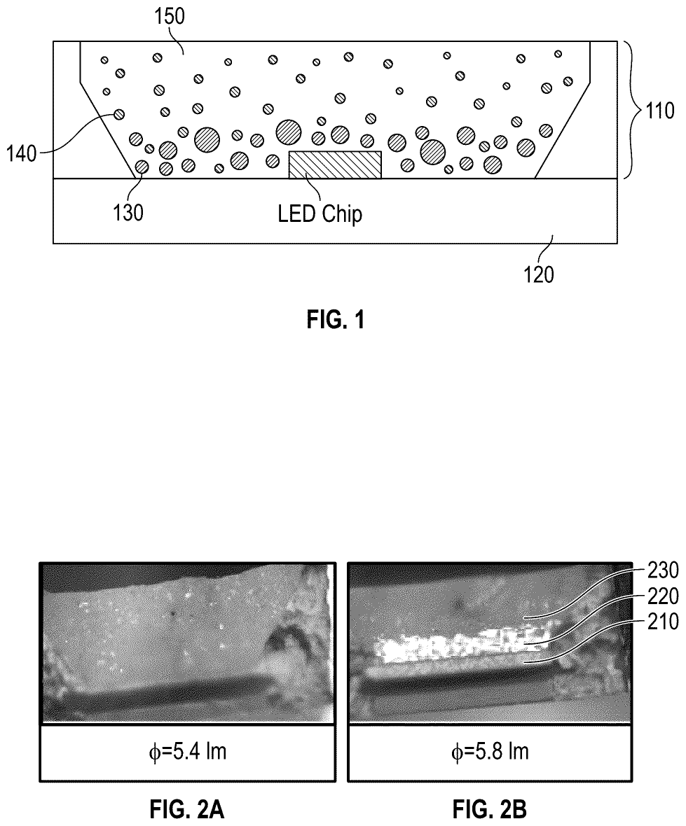

According to one or more embodiments, the light conversion LED package contains a layered structure. FIG. 1 is a depiction of one such embodiment of the current disclosure. The layered structure 110 includes a red fluorescent material 130, a green fluorescent material 140, and a curable resin 150.

As will be described in greater detail below, the present disclosure refers to layers or layering of fluorescent materials with different wavelengths. As it relates to the current disclosure, a layer refers to an area of the layered structure containing a majority of red fluorescent materials (i.e., red layer) and an area of the layered structure containing a majority of green fluorescent materials (i.e., green layer). For example, the red layer may contain at least 50%, 55%, 60%, 70%, 80%, 90%, 95% 98%, 99% or 100% by volume of red fluorescent material based on the total volume of fluorescent material in the red layer. Similarly, the green layer may contain at least 55%, 60%, 70%, 80%, 90%, 95% 98%, 99% or 100% by volume of green fluorescent material based on the total volume of fluorescent material in the green layer. The area where the red fluorescent material and the green fluorescent material come into contact with one another (also referred to as a “middle zone”) may be a mixture of the red fluorescent material and the green fluorescent material. However, according to embodiments of the current disclosure, the amount of the red fluorescent material may be greater than the amount of the green fluorescent material in the middle zone.

In one or more embodiments, the layered structure 110 is on top of a substrate 120. The substrate may be any substrate that is known in the art for LEDs. According to one or more embodiments, the substrate is a plastic printed circuit board. Examples of suitable substrate materials include polyphthalamide (PPA), poly (1,4-cyclohexanedicarbinol terephthalate (PCT), epoxy molding compounds (EMC), and combinations thereof.

In one or more embodiments, the layered structure 110 has a red fluorescent material 130, depicted as red fluorescent dots 130 in FIG. 1. The red fluorescent material 130 may be a phosphor or a quantum dot. The quantum dot may be a perovskite quantum dot, a carbon dot, a graphene quantum dot, a semiconductor nanocrystalline quantum dot, and combinations thereof. In some embodiments, the red fluorescent material 130 is spherical or nearly spherical. In some embodiments, the red fluorescent material 130 has a narrow size distribution such that it has a full-width half maximum (FWHM) of equal to or less than 30 nanometers, as measured by photoluminescence spectroscopy. Non-limiting examples of the red fluorescent material 130 are a red K₂SiF₆:Mn⁴⁺ phosphor or red CdSe/ZnS quantum dots. The red fluorescent material 130 may include an A₂MF₆:Mn⁴⁺ red phosphor, where A is an alkali metal and M is Si, Ge, Sn, Ti, Zr or Hf (e.g., K₂SiF₆:Mn⁴⁺). The red fluorescent material 130 may further include MSe₁₋ₓSₓ:Eu, wherein M is at least one of Mg, Ca, Sr, Ba and Zn and 0<x<1.0. The red and green fluorescent materials are known in the art and are readily available commercially. According to one or more embodiments, the red fluorescent material 130 has an emission peak wavelength between 600 and 690 nm.

In one or more embodiments, the layered structure 110 has a green fluorescent material 140. The green fluorescent material 140 may be a phosphor or a quantum dot. The quantum dot may be a perovskite quantum dot, a carbon dot, a graphene quantum dot, a semiconductor nanocrystalline quantum dot, and combinations thereof. In some embodiments, the green fluorescent material is spherical or nearly spherical. Exemplary quantums dot include, but are not limited to, group II-VI semiconductors such as CdS, CdSe, CdS/ZnS, CdSe/ZnS or CdSe/CdS/ZnS, group II-VI semiconductors, such as CdTe, ZnSe, ZnTe, ZnS, HgTe, HgS, HgSe, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, group III-V or group IV-VI semiconductors such as GaN, GaP, GaNP, GaNAs, GaPAs, GaAs, GaAlNP, GaAlNAs, GaAlPAs, GaInNP, GaInNAs, GaInPAs, AlN, AlNP, AlNAs, AlP, AlPAs, AlAs, InN, InNP, InP, InNAs, InPAs, InAS, InAlNP, InAlNAs, InAlPAs, PbS/ZnS or PbSe/ZnS, group IV semiconductors, such as Si, Ge, SiC, and SiGe, chalcopyrite-type compounds, including, but not limited to, CuInS₂, CuInSe₂, CuGaS₂, CuGaSe₂, AgInS₂, AgInSe₂, AgGaS₂, AgGaSe₂ or perovskite quantum dots having a formula of ABX₃ where A is cesium, methylammonium or formamidinium, B is lead or tin and C is chloride, bromide or iodide.

According to one or more embodiments, the green fluorescent material 140 has an emission peak wavelength between 500 and 570 nm. In some embodiments, the green fluorescent material 140 may have an emission peak wavelength between 520 and 550 nm based on the desired display field.

According to one or more embodiments, the layered structure 110 has a red fluorescent material 130 that is closer to the substrate than the green fluorescent material 140. As will be described in greater detail below, various methods may be used to control the location of the red fluorescent material 130 with respect to the green fluorescent material 140. Once the layered structure 110 is formed, a blue light may be used to transmit light through the substrate 120 and the layered structure 110. The blue light excites the fluorescent materials in the layered structure 110 to produce a white light.

In one or more embodiments, the layered structure 110 contains a curable resin 150. The curable resin 150 may be UV curable or thermally curable. The curable resin 150 may be an alkyl-phenyl silicone resin or an epoxy resin. The alkyl-phenyl silicone resin may be a methyl-phenyl silicone resin. The methyl-phenyl silicone resin may have different ratios of methyl groups to phenyl groups. As is understood by those skilled in the art, the ratio of methyl groups to phenyl groups may depend on the refractive index desired of the curable resin 150. According to one or more embodiments, the refractive index of the curable resin 150 is from 1.40 to 1.56. The ratio of methyl groups to phenyl groups may depend on the density desired of the curable resin. According to one or more embodiments, the density of the curable resin 150 is from 1.05 to 1.15 g/cm³. Resins having suitable properties for particular applications may be chosen and are readily available commercially.

Embodiments of the present disclosure relate to methods for making a layered structure as described above with reference to FIG. 1. The first step of a method may be mixing a red fluorescent material and a green fluorescent material with a curable resin to produce an adhesive mixture. The next step of the method may be dispensing the adhesive mixture on a substrate. The method described herein focuses on modifying the adhesive mixture so that the red fluorescent material and the green fluorescent material form two layers on top of the substrate (i.e., one red layer and one green layer). The longer wavelength material is disposed closest to the substrate and the shorter wavelength material is disposed farther away from the substrate. The modification of the adhesive mixture to form the layers may be done through centrifuging. The layers may be formed by appropriately selecting the particle size or density of each fluorescent material and the curable resin to control where the different fluorescent materials settle via gravitational forces during centrifuging. After centrifuging, the last step of method may be curing the layered structure onto the substrate. The method may result in a final layered structure where the red fluorescent material is layered closer to the substrate than the green fluorescent material.

Controlling the layering of the different fluorescent materials is based on the settling velocity, as described by Equation 1 below.

$${u}_{i} = \sqrt{\frac{4 dg ( {ρ}_{i} - ρ )}{3 ρξ}} \qquad ( Equation l )$$

In Equation 1, uᵢ is the settling velocity, d is the diameter, g is the gravity constant, pi is the density of the fluorescent materials, p is the density of the curable resin, and is the drag coefficient. With respect to particle size, when the diameter of the red fluorescent material (d_{red}) is greater than the diameter of the green fluorescent material (d_{green}), the red fluorescent material may have a higher settling velocity than the green fluorescent material. This may result in the red fluorescent material layering closer to the substrate in the layered structure. With respect to density, a similar effect may be seen where when the density of the red fluorescent material minus the density of the curable resin (ρ_{red}−ρ) is greater than the density of the green fluorescent material minus the density of the curable resin (p_{green}−ρ), the red fluorescent material may have a higher settling velocity and thus layer closer to the substrate. With respect to the drag coefficient, a larger drag coefficient is positively correlated to a higher settling velocity, where a fluorescent material with a larger drag coefficient may layer closer to the substrate.

In one or more embodiments, a method of making a layered structure begins with mixing a red fluorescent material and a green fluorescent material with a curable resin to produce an adhesive mixture. The red fluorescent material and green fluorescent material are as described previously. The red fluorescent material may be included in the adhesive mixture in a concentration of 5 to 40 weight percent (wt %) based on the total weight of the adhesive mixture. The red fluorescent material may be included at a concentration with a lower limit of any one of 5 wt %, 10 wt %, 15 wt %, and 20 wt %, and a upper limit of any one of 21 wt %, 25 wt %, 30 wt %, and 40 wt %, where any lower limit may be paired with any mathematically compatible upper limit. The green fluorescent material may be included in the adhesive mixture in a concentration of 2 to 15 wt % based on the total weight of the adhesive mixture. The green fluorescent material may be included at a concentration with a lower limit of any one of 2 wt %, 5 wt %, and 7 wt %, and a upper limit of any one of 8 wt %, 10 wt %, 12 wt %, and 15 wt %, where any lower limit may be paired with any mathematically compatible upper limit.

The red fluorescent material, the green fluorescent material, and the curable resin may be mixed by suitable methods known in the art in order to form a homogeneous mixture. For example, in one or more embodiments, the mixing is conducted using a vacuum stirring and defoaming machine. The vacuum stirring and defoaming machine may be any machine known to those skilled in the art. The vacuum pressure of the vacuum stirring and defoaming machine may be equal to or less than 5 kPa. The adhesive mixture may be mixed for a period of time of 3 to 20 minutes. The conditions of the vacuum stirring and defoaming machine may include a revolution speed of 300 to 3000 rpm and a self-rotation speed of 200 to 800 rpm.

In one or more embodiments, the adhesive mixture may include various additives. As will be explained in greater detail below, additives may be used in specific embodiments for specific purposes. The additives may be solvents, oligosilanes, thickeners, fumed silica particles, and combinations thereof. The additives may change the viscosity of the curable resin. According to one or more embodiments, the viscosity of the adhesive mixture at 25° C. may range from 7,000 to 1,000,000 cP (centipoise). According to further embodiments, the viscosity of the adhesive mixture at 25° C. may range from 500,000 to 700,000 cP. Changing the viscosity of the curable resin may be done so that the curable resin has enough fluidity that the red fluorescent material separates in the adhesive mixture to be closer to the substrate than the green fluorescent material due to centrifuging. Changing the viscosity of the curable resin may also be done so that the curable resin has a high enough viscosity to ensure that the green fluorescent material remains farther from the substrate than the red fluorescent material due to centrifuging. For example, additives such as acetone, ethyl acetate, toluene, cyclohexane, oligosilanes, and combinations thereof may be used to regulate the viscosity. The amount of additive may depend on how much is needed for the viscosity to reach 7,000 to 1,000,000 cP. According to one or more embodiments, the additives are mixed at a range from 0 to 20 wt %.

In one or more embodiments, the next step in a method for making a layered structure is dispensing the adhesive mixture onto a substrate. The adhesive mixture may be dispensed into an encapsulation cavity of an LED holder using an adhesive dispenser. The LED holder may have an LED size of 2204, 2604, 3006, 3806, 2016, 4014, 7020, 3528, or 3030. As known to those skilled in the art, the LED size is abbreviated so that the length and width is listed. For example, 2204 corresponds to sizes of 2.2 millimeters in length and 0.4 millimeters in width.

In one or more embodiments, the next step in a method for making a layered structure is centrifuging the adhesive mixture so that the red fluorescent material and the green fluorescent material separate in the adhesive mixture to form a layered structure. Separating the red fluorescent material and the green fluorescent material is done in a manner where the red fluorescent material may be layered closer to the substrate than the green fluorescent material. As pictured in FIG. 1, one embodiment of the layered structure has a red fluorescent material adjacent to the substrate and a green fluorescent material adjacent to the red fluorescent material. Other embodiments of the layered structure include the green fluorescent material remaining suspended in the curable resin (see Example 3, FIG. 2B) while the red fluorescent material forms a layer adjacent to the substrate.

According to one or more embodiments, the adhesive mixture is centrifuged. The time for centrifuging may be from 1 to 5 minutes. The speed for centrifuging may be from 500 to 4000 rpm. The time and speed for centrifuging may vary based on the type of red fluorescent and green fluorescent materials used.

During centrifuging, the red fluorescent material may be layered on the substrate closer than the green fluorescent material. This difference in the settling velocities of the red and green fluorescent materials may be achieved using a variety of techniques including selecting different particle sizes, selecting different densities, coating the materials to modify the particle size, coating the materials to modify the density, adding in additives to modify the viscosity of the curable resin, and centrifuging at different temperatures.

According to one or more embodiments, using different particle sizes of the red fluorescent material and green fluorescent material will result in the red fluorescent material having a higher settling velocity than the green fluorescent material during centrifugation thereby forming a layer closer to the substrate. Materials with a larger average particle size will settle onto the substrate faster than materials with a smaller average particle size. In one or more embodiments, the average particle size of the red fluorescent material is greater than the average particle size of the green fluorescent materials. For example, the average particle size of the red fluorescent material may be greater than that of the average particle size of the green fluorescent material by 1.5 to 10,000 times. The average particle size of the red fluorescent material may be greater than that of the average particle size of the green material by an amount ranging from a lower limit of any of 1.5, 10, 100, 500, 1,000, 3,000, and 5,000 times to an upper limit of any of 100, 500, 1,000, 5,000, 8,000, and 10,000 times, where any lower limit can be used in combination with any mathematically-compatible upper limit. The average particle size of the red fluorescent material may be from 5 nm to 100 μm. The average particle size of the green fluorescent material may be from 10 nm to 60 nm.

According to one or more embodiments, using different densities of the red fluorescent material and the green fluorescent material will result in the red fluorescent material having a higher settling velocity than the green fluorescent material during centrifugation. Materials with a greater density will settle onto the substrate faster than materials with a lesser density. In one or more embodiments, the density of the red fluorescent material minus the density of the curable resin is greater than the density of the green fluorescent materials minus the density of the curable resin. For example, the density of the red fluorescent material minus the density of the curable resin may be greater than that of the green fluorescent material minus the density of the curable resin by at least 1.5 times. In one or more embodiments, the density of the red fluorescent material minus the density of the curable resin is from 1.0 to 2.5 g/cm³. In one or more embodiments, the density of the green fluorescent material minus the curable resin is from 0 to 1.5 g/cm³.

In one or more embodiments, prior to mixing, the method includes modifying the red fluorescent material with a modifying material. The modifying material is selected such that it will undergo a chemical reaction with itself or with another modifying material that is on the surface of another red fluorescent material or another particle as explained below. The reaction may be a click chemistry reaction or a condensation reaction. The interaction of the modifying material by a click chemistry reaction or a condensation reaction may lead to aggregation of the red fluorescent material. As the red fluorescent material forms larger aggregates, the apparent particle size increases. As explained above, a larger particle size leads to a higher settling velocity of the red particle during centrifugation

In one or more embodiments, the modifying material includes at least two functional groups capable of undergoing a click chemistry reaction. The functional groups may be included so that one red fluorescent material is modified with one functional group, while another red fluorescent material is modified with a second functional group. When the two red fluorescent materials combine, the click chemistry reaction between the two functional groups may occur where the functional groups “click” together. Due to the click chemistry reaction, the apparent particle size of the red fluorescent material may increase. As described above, an increase in particle size may lead to a higher settling rate of the red fluorescent material during centrifugation.

According to one or more embodiments, the click chemistry reaction occurs between an alkynyl and an azide group. As such, the modifying material may have either an alkynyl and an azide group. In other embodiments, the click chemistry reaction occurs between a transcyclooctenyl and a tetrazine group. The selection of the click chemistry coating material depends on the click chemistry reaction. For example, the modifying material with an alkyne is grafted on one set of red fluorescent materials. Another set of red fluorescent materials is grafted with the modifying material containing an azide. The two sets are mixed in the adhesive mixture. When the two sets come into contact, the alkyne and azide “click” together, thus increasing the apparent particle size of the red fluorescent material. In another example, one set of red fluorescent materials may be divided into two parts. The modifying material with an alkyne may be grafted on one part. The other part may be grafted with the modifying material containing an azide. The click chemistry modifying material may be grafted on the red fluorescent materials through ligand exchange process to replace some of the original ligands present on the fluorescent materials. In one or more embodiments, the original ligands may be replaced with propargyl-PEG4-thiol or azide-PEG-thiol, The click chemistry modifying material may be added at a molar excess of 5 to 20 times the amount of the red fluorescent material. The resultant amount of click chemistry modifying material on the red fluorescent material may be from 0.3 to 3 wt %.

According to one or more embodiments, the modifying material on the red fluorescent material includes a functional group that reacts with another same functional group by condensation. Condensation of the modified red fluorescent material with the same functional group in the adhesive mixture may lead to coupling of the red fluorescent material together. Increasing the particle size may lead to the red fluorescent material settling faster than the green fluorescent material during centrifugation. The modifying material may contain silanol or methoxysilane groups. For example, one set of red fluorescent material may be grafted with the modifying material containing a silanol. Another set of red fluorescent material may also be grafted with the modifying material containing a silanol. The hydroxides in the silanols may react via a condensation reaction. In another example, a set of red fluorescent materials may be divided into two parts. The modifying material with a silanol may be grafted on one part. The other part may be grafted with the modifying material also containing a silanol. The condensation modifying material may be grafted on the red fluorescent materials through ligand exchange process to replace some of the original ligands present on the fluorescent materials. In one or more embodiments, the modifying material including a silanol or methoxysilane group is added at a molar ratio of about 1:1 or 5:1 of the silanol or methoxysilane group to the red fluorescent material. However, a molar ratio ranging from 1:2 to 2:1 or 3:1 to 20:1 of the silanol or methoxysilane group to the red fluorescent material may be used.

According to one or more embodiments, the modifying material on the red fluorescent material includes a functional group that reacts with an inorganic oxide particle by condensation of hydroxyl groups. Condensation of the modified red fluorescent material with inorganic oxide particles in the adhesive mixture may lead to coupling of the red fluorescent material with the inorganic oxide particles. The coupling may increase the average particle size of the red fluorescent material. Increasing the particle size may lead to the red fluorescent material settling faster than the green fluorescent material during centrifugation. The modifying material may contain silane coupling agents. For example, agents such as —SH functional groups and —NH₂ functional groups may react with oxides on the surface of the inorganic oxide particle via condensation. For example, silane coupling agents may include trimethoxysilylpropanethiol, 3-aminopropyltrimethoxysilane, 3-mercaptopropyltriethoxysilane, or [3-(1-piperazinyl)propyl]trimethoxysilane, The silane coupling agents may be grafted on the red fluorescent materials through ligand exchange process to replace some of the original ligands present on the fluorescent materials. In one or more embodiments, the red fluorescent material is added at a weight ratio of 10 to 1000 times the modifying material.

In one or more embodiments, the adhesive mixture further includes an inorganic oxide particle for reacting with the aforementioned coating material condensation of hydroxyl groups. The inorganic oxide particle may be Al₂O₃, TiO₂, ZrO₂, SiO₂, ZnO, ZnMgO, SnO₂, or combinations thereof. Hydroxyl groups on the surface of the inorganic oxide particles may react via condensation of the hydroxyl groups with the silane coupling agents in the coating material of the red fluorescent materials, as described above. In one or more embodiments, the inorganic oxide particle is added at a weight ratio of 1 to 10 times the red fluorescent material.

According to one or more embodiments, the coating material on the red fluorescent material is an inorganic oxide. Coating with the inorganic oxide may alter the density of the red fluorescent material. Coating with the inorganic oxide may further affect the interaction with the curable resin. The density of the red fluorescent material coated minus the density of the curable resin may be controlled to be at least 1.5 times greater than the density of the green fluorescent material minus the density of the curable resin. That is, regardless of the coating material, in one or more embodiments, the red fluorescent material will layer closer to the substrate than the green fluorescent material during centrifuging.

Coating the red fluorescent material with the inorganic oxide may be done using a sol-gel method. The sol-gel method is known by those skilled in the art to include dissolving a molecular precursor in water or alcohol and converting the precursor to a gel by heating and stirring through hydrolysis or alcoholysis. According to one or more embodiments, the precursor is tetraethyl orthosilicate (TEOS), methyl triethoxysilane (MTEOS), sodium silicate, lithium silicate, kalium silicate, aluminum isopropoxide, tripropylorthoaluminate Al(OC₃H₇)₃ (TPOAI), titanium alkoxide, vanadium alkoxide, and combinations thereof. After hydrolysis/alcoholysis, the coated red fluorescent material may be purified and dried. The resultant coating material may be Al₂O₃, TiO₂, ZrO₂, SiO₂, ZnO, ZnMgO, SnO₂, or combinations thereof. The amount of inorganic oxide coating material may be from 0.2 to 5 wt % greater than the red fluorescent material.

In one or more embodiments, the green fluorescent material may be coated with a coating material. The coating material may be selected so that it decreases the density of the green fluorescent material minus the density of the curable resin. The density may be decreased by a coating material that is an inorganic oxide or a polymer.

The coating material on the green fluorescent material may be an inorganic oxide. Coating with the inorganic oxide may decrease the density of the green fluorescent material minus the density of the curable resin. The density of the inorganic oxide prepared by a sol-gel method (described below) can be less than the green fluorescent material. By coating with the inorganic oxide, volume is added to the green fluorescent material without a notable increase in mass. Thus, the average density of coated green fluorescent material can be controlled to be less than the uncoated fluorescent material. The amount of coating may affect the decrease in density. The density of the green fluorescent material coated with the inorganic oxide minus the density of the curable resin may remain at least 1.5 times less than the density of the red fluorescent material minus the density of the curable resin. The red fluorescent material may be coated or uncoated in such embodiments. Regardless of the selection of the inorganic oxide coating material, in one or more embodiments, the red fluorescent material will layer closer to the substrate than the green fluorescent material during centrifugation.

Coating the green fluorescent material with the inorganic oxide may be done using a sol-gel method. The inorganic oxide coating may be Al₂O₃, TiO₂, ZrO₂, SiO₂, ZnO, ZnMgO, SnO₂, or combinations thereof. The amount of coating material may be from 5 to 300 wt % greater than the green fluorescent material.

According to one or more embodiments, the coating material on the green fluorescent material is a polymer. The polymer coating material may reduce the density of the green fluorescent material minus the curable resin as compared to the red fluorescent material minus the curable resin. Polymers chosen for the coating material are less dense than the green fluorescent material. The amount of polymer coating may decrease in the effective density of the green fluorescent material. Reducing the density of the green fluorescent material with the polymer may result in the red fluorescent material layering closer to the substrate than the green red fluorescent material during centrifugation.

Coating the green fluorescent material with a polymer coating material may be done by ligand exchange. The original ligands may be exchanged with polymer ligands containing thiol, amino, carboxyl, or phosphates as end groups. The polymer coating material on the green fluorescent material may be polyvinyl alcohol, polymethyl methacrylate, polycarbonate, epoxy resin, and combinations thereof. The choice of polymer coating material may depend on the ratio of the density of the green fluorescent material as compared to the red fluorescent material. Regardless of the polymer coating, the density of the green fluorescent material minus the density of the curable resin may be at least 1.5 times less than the red fluorescent material minus the density of the curable resin. The amount of the polymer coating may be from 30 to 100 wt % of the green fluorescent material.

According to one or more embodiments, the green fluorescent material includes a modifying material with a functional group that increases the compatibility of the green fluorescent material with the curable resin. Increased capability of the green fluorescent material with the curable resin may lead to the green fluorescent material having a lower settling velocity as compared to an uncoated red fluorescent material. The modifying material may contain silane or phenyl groups. The silane or phenyl groups may have increased compatibility with the curable resin. The modifying material may be coated on the green fluorescent material by ligand exchange. In one or more embodiments, the modifying material is added at a weight ratio of 0.1 to 5 times the green fluorescent material. In other embodiments, the modifying material is added at a molar ratio of 5 to 20 times the green fluorescent material.

Rather than changing the density of the green fluorescent material, a modifying material may instead be used so that the green fluorescent material has a lower settling velocity as compared to the red fluorescent material during centrifugation. For example, a modifying material that includes a silane will interact with the methyl-phenyl silicone curable resin and stay suspended.

According to one or more embodiments, the modifying material (through grafting) on the green fluorescent material is a silane. Modifying the green fluorescent material with a silane may make the green fluorescent material have stronger interactions with the curable resin. For example, the green fluorescent material may exhibit stronger dispersion forces, dipole-dipole interactions, and/or hydrogen bonding, among others with the curable resin. In one or more embodiments, the curable resin is a methyl phenyl silicone resin. The green fluorescent material interacting with the curable resin may lead to the red fluorescent material layering closer to the substrate than the green fluorescent material during centrifugation.

Modifying the green fluorescent material with a silane material may be done by ligand exchange. Some of the original ligands may be exchanged with methyl-phenyl silicones containing thiol, amino, carboxyl, or phosphate groups. The ratio of methyl to phenyl groups in the methyl-phenyl silicones may be about the same as the ratio of methyl to phenyl groups in the curable resin. A non-limiting example of a silane may be oligomeric mercaptosilanes. The amount of the silane material may be from 0.5 to 5 wt % of the green fluorescent materials.

In one or more embodiments, prior to mixing, the method includes modifying both the red fluorescent material and the green fluorescent material with a modifying material. As previously described, modifying may be done based on the ability to modify the particle size or the density of the fluorescent material. The modifying may also change the electrostatic interactions with the resin. Regardless of the modifying material, according to one or more embodiments, the red fluorescent material is layered closer to the substrate than the green fluorescent material during centrifugation.

The centrifuging may be conducted at ambient temperature. However, in one or more embodiments, it may be advantageous to centrifuge the adhesive mixture at an elevated or decreased temperature. Increasing the temperature to be in a range of 50 to 120° C. may result in the red fluorescent material precipitating from the adhesive mixture. The choice of the red fluorescent material may be based on the ability to precipitate in the desired temperature range. For example, the red fluorescent material may be coated with a polymer (such as polyvinyl acetate or an acrylic acid-methacrylic acid copolymer) with a glass transition temperature in the range of the temperature increase. When the coated red fluorescent material is heated above the glass transition temperature, the coated polymer chains will have increased mobility, which may lead to a tendency to aggregate together. Precipitation of the red fluorescent material may increase the apparent particle size. As previously discussed, an increase in particle size may lead to the red fluorescent material layering closer to the substrate than the green fluorescent material during centrifugation. Decreasing the temperature to be in a range of −20 to 5° C. may also result in the red fluorescent material precipitating from the adhesive mixture. The choice of the red fluorescent material may be based on the ability to precipitate in the desired temperature range. For example, the red fluorescent material may be coated with a long branched polymer or a polymer with a low glass transition temperature of less than 40° C. Examples of long branched polymers may include polyvinyl acetate or an acrylic acid-methacrylic acid copolymer. Examples of polymers with low glass transition temperatures may include polylactic acid, polycaprolactone, or polyisobutylene. The polymer may be less soluble in the adhesive mixture, leading to precipitation from the adhesive mixture. Precipitation of the red fluorescent material may increase the apparent particle size. As previously discussed, an increase in particle size may lead to the red fluorescent material layering closer to the substrate than the green fluorescent material during centrifugation.

In one or more embodiments, the method of centrifuging the adhesive mixture where the red fluorescent material and green fluorescent material separate to form a layered structure includes using a carrier. The carrier may serve as a vehicle for layering the red fluorescent material on the substrate prior to the green fluorescent material. For example, the carrier is selected so that the pore size is smaller than the green fluorescent material but larger than the red fluorescent material. The carrier adsorbs the red fluorescent material into the pores and enables it to be layered closer on the substrate during centrifugation, while blocking the green fluorescent material. The carrier may have a varied pore size based on the average particle size or ion charge of red fluorescent material and green fluorescent material.

The carrier may be a mesoporous material or a molecular sieve. The mesoporous material may be an ion exchange resin. The mesoporous material may be Al₂O₃, TiO₂, ZrO₂, SiO₂, ZnO, ZnMgO, or SnO₂. The molecular sieve may be a silicoaluminophosphate or aluminophosphate molecular sieve. The carrier may be added at a 1 to 5 times mass ratio of carrier to the red fluorescent material to ensure adsorption.

The method of making a layered structure may be adjusted such that a partial curing and inversion of the material is conducted prior to forming a fully layered structure. In such embodiments, the adhesive mixture is centrifuged so that the red fluorescent material and green fluorescent material separate to form a layered structure. Then, the centrifuged adhesive mixture may be partially cured through precuring. The partial curing does not completely cure the resin rendering the red fluorescent material and the green fluorescent material immobile in the layered structure. Instead, the partial curing still allows for some movement of the fluorescent materials. Then the partially cured adhesive mixture may be inverted. Inversion of the partial cured layered structure results in both materials settling away from the substrate. However, the red fluorescent material is still closer to the substrate than the green fluorescent material. The inversion may produce a layered structure where the red fluorescent material and the green fluorescent material are not adjacent to the substrate. The resulting section of curable resin that does not include either the red fluorescent material or the green fluorescent material may result in the ability to achieve a remote excitation structure. A remote excitation structure is known to improve the stability of fluorescent materials.

Once suitable layers of the red and green fluorescent materials are formed via any of the techniques described above, the layered structure may be cured to form the layered structure of the LED as noted above. Curing is required for curable resin to harden on the substrate, thereby immobilizing the red fluorescent material and the green fluorescent material. Curing may be done through baking the layered structure and the substrate in an oven. The time period for curing may be from 0.5 to 1 hour. The temperature for curing may be in a range of 80 to 120° C.

Curing may be done through ultra-violet light (UV). Curing by UV may include the use of an acrylate, acryloxy, or epoxy based UV curable resin. The wavelengths for curing by UV may be from 330 to 400 nm. The UV light may be supplied at a power from 10 to 100 mW/cm³ for a time period ranging from 10 seconds to 2 minutes.

Embodiments of the present disclosure relate to other methods for making a layered structure. In such embodiments, a red fluorescent material and a green fluorescent material may be mixed with a curable resin to produce an adhesive mixture. The next step of the method may be dispensing the adhesive mixture on a substrate. The method described herein focuses on modifying the adhesive mixture so that the red fluorescent material is layered closer to a substrate than the green fluorescent material. Modifying the adhesive mixture may be through applying an external field. Applying the external field may control the separation of the red fluorescent material and the green fluorescent material in the adhesive mixture. Then, the layered structure may be cured onto the substrate. The method may result in a final layered structure where the red fluorescent material is layered closer to the substrate than the green fluorescent material.

In one or more embodiments, the method of making a layered structure begins with mixing a red fluorescent material and a green fluorescent material with a curable resin to produce an adhesive mixture. The mixing of the red fluorescent material and the green fluorescent material may be as described above.

In one or more embodiments, the next step in a method for making a layered structure is dispensing the adhesive mixture onto a substrate. The dispensing step may be as described above.

In one or more embodiments, the next step in a method for making a layered structure is modifying the adhesive mixture so that the red fluorescent material and the green fluorescent material separate to form a layered structure. Modifying may occur by applying an external field to control the separation. The adhesive mixture may be altered to respond to the external field in a way that controls the separation. As will be described in further detail below, alteration may occur through coating the fluorescent materials with a coating material. The external field may be an electric field. The electric field may be applied in a range of 1 to 50 volts/cm. The device for applying the electric field may be an electric field separator. The electric field separator may include several electrode plates arranged substantially parallel and spaced apart so that the polarities of adjacent electrode plates are different from each other.

The red and green fluorescent materials may be coated with a charged coating material to yield a response to the applied electric field. For example, one fluorescent material is coated with a positively charged coating material, such as a coating material that includes an amino group. The other fluorescent material may be coated with a negatively charged coating material, such as a coating material that includes a carboxyl group. Thus, when the electric field is applied, the charged coating material on the fluorescent materials will lead to separation based on their attraction to the negatively charged cathode or the positively charged anode. Those materials coated with a negatively charged coating material will separate closer to the positively charged anode. Those materials coated with a positively charged coating material will separate closer to the negatively charged cathode.

The negatively charged coating material may include an amino group. Suitable examples of coating materials having an amino group are amino containing siloxanes. The positively charged coating material may include a carboxyl group. Suitable examples of coating materials having the carboxyl group are carboxyl containing siloxanes. The charged coating material is coated on the fluorescent materials by ligand exchange or surface grafting. The molar ratio of the negatively charged or positively charged groups may be 10 to 10,000 times that of the fluorescent material.

In other embodiments, a magnetic field is used to modify the adhesive mixture. The adhesive mixture may be altered to respond to the magnetic field that leads to separation of the red fluorescent material and the green fluorescent material. As will be described in further detail below, alteration may occur through coupling of one of the fluorescent materials to a magnetic particle. The magnetic field may be applied by a magnetic separation device. The magnetic field may also be applied using a rare earth magnet, such as neodymium, or an electromagnet.

In embodiments where a magnetic field is used to modify the adhesive mixture, the adhesive mixture may include a magnetic particle coupled to the fluorescent material, as described in further detail below. The magnetic particle may be used to promote the separation of the red fluorescent material and the green fluorescent material when applying a magnetic field. The magnetic particles may be Fe₂O₃, Fe₃O₄, CoFe₂O₄, MnFe₂O₄, NiFe₂O₄, FeCo, FeNi, NdFeB, LaCo, or combinations thereof. The choice of magnetic particle may depend on the magnetization intensity of the magnetic particle. The magnetization intensity may be equal to or greater than 20 emu/gram. In one or more embodiments, superparamagnetic nanomaterials are used as the magnetic particle. The magnetic particles may have a coating material to improve the light efficacy of the layered structure. As the magnetic particles are typically made of materials that absorb UV light, the coating material may be TiO₂, ZnO, Al₂O₃, ZrO₂, or any other metal oxides known in the art that reflect UV light. The magnetic particles may be included in the adhesive mixture at a mass ratio of 0.1 to 5 times the amount of red fluorescent materials. In one or more embodiments, the magnetic particles may be included in the adhesive mixture at a mass ratio of 1 to 1 times the amount of red fluorescent materials.

According to one or more embodiments, prior to mixing, the method of making a layered structure includes modifying the fluorescent material with a coupling material. The coupling material may include a functional group that may be grafted on the fluorescent material. The coupling material may be functional groups that react with the functional group of the magnetic particle. Examples of the coupling material include trimethyl orthosilicate, where interaction with the fluorescent material produces a silane on the surface. For example, the silane may interact with the hydroxyl of the oxide coating of the magnetic particle and enable the separation to be controlled by applying the magnetic field. Other coupling materials may include mercaptobutyric acid, 3-mercaptopropylmethyldimethoxysilane, or 4-triethoxysilylaniline. Modifying with the functional groups may be done by ligand exchange. The amount of coupling material may be from 0.5 to 5 wt % of the fluorescent materials.

Once suitable layers of the red and green materials are formed, the layered structure may be cured to form the layered structure of the LED as noted above.

Embodiments of the present disclosure also relate to methods for making a layered structure using phase separation for modifying the adhesive mixture. The method described herein focuses on phase separating the adhesive mixture so that the red fluorescent material is layered closer to a substrate than the green fluorescent material. Phase separation is done through using at least two phases where the phases are immiscible. One phase may be the curable resin, which is non-polar. The second phase may be a low-density polar solvent. The method may result in a final layered structure where the red fluorescent material is layered closer to the substrate than the green fluorescent material.

In one or more embodiments, phase separation of the adhesive mixture occurs when the green fluorescent material is dissolved in a low-density polar solvent. The red fluorescent material is dissolved in a non-polar based solvent, such as the curable resin. As the solvents are immiscible, they will separate in the adhesive mixture.

The green fluorescent material may be dissolved in a low-density polar solvent. Examples of the low-density polar solvent are water, methanol, and ethanol. The green fluorescent material may be dissolved in the low-density polar solvent at a concentration of 20 to 50 wt %. The red fluorescent material may be dispersed with the curable resin. The green fluorescent material and the low-density solvent may produce a microemulsion within the curable resin. During centrifugation, the red fluorescent material may layer closer to the substrate, as it is not suspended in the microemulsion as the green fluorescent material is.

According to one or more embodiments, prior to mixing, the method of making a layered structure includes coating the green fluorescent material in a coating material. The coating material may be a polar ligand. The polar ligand coating material may improve the solubility of the green fluorescent material in the low-density polar solvent for phase separation. The polar ligand coating material may be mercaptohexanol, mercaptopropanol, cysteine, glutathione, mercaptoacetic acid, mercaptopropionic acid, glutaric acid, polyethyleneimine, carboxy polyethylene oxide, or combinations thereof. The green fluorescent material may be coated by the polar ligand coating material by ligand exchange. The amount of polar ligand coating material on the green fluorescent material may be 10 to 1,000 moles greater than the green fluorescent material.

During mixing of the polar ligand coated green fluorescent material, the red fluorescent material, and the curable resin with the low-density polar solvent, a microemulsion dispersion of the low-density polar solvent may form with the curable resin. The term “microemulsion” is used to describe a fine dispersion of one liquid in another in which the liquids are immiscible. In a microemulsion, the droplets formed are micron in size. The coated green fluorescent material may be dissolved in the low-density polar solvent (the water phase), where the red fluorescent material may be dispersed in the curable resin or a non-polar solvent (the oil phase). The low-density polar solvent with the green fluorescent material may settle above the red fluorescent material and the curable resin, which may lead to a phase separation. The phase separation may be further modified via centrifugation or it may be allowed to naturally settle.

According to one or more embodiments, once phase separation has occurred, the adhesive mixture is dried. During drying, the red fluorescent material may be layered closer to the substrate than the green fluorescent material. Drying may be done by vacuum drying. The vacuum requirement may include a pressure less than or equal to 3000 Pa, a temperature greater than or equal to 100° C., and a time period ranging from 1 to 5 hours.

Once suitable layers of the red and green materials are formed, the layered structure may be cured to form the layered structure of the LED as noted above.

Embodiments of the present disclosure may provide at least one of the following advantages. The separation of the red fluorescent material and the green fluorescent material may improve the excitation efficiency of the red fluorescent material. Further, the separation may reduce the re-excitation of green light by the red fluorescent material. These advantages may combine to improve the luminous efficiency of the LED device. Most significantly, the methods described herein require one adhesive mixture, one step for layering, and one step for curing. Current methods known in the art require at least two adhesive mixtures, two steps for layering, and two steps for curing for each layer.

### Examples

Example 1: K₂SiF₆:Mn⁴⁺ red phosphor (Denka Company, Japan) was used as the red fluorescent material, the particle size being 10-40 m. CdSe/ZnS green quantum dots were used as the green fluorescent material, the particle size being 6 to 40 nm. 50 parts (calculated by weight parts) of thermal curable methyl-phenyl silicone resin, 30 parts of red phosphor, and 20 parts of green quantum dots were weighed, mixed evenly and then placed in a vacuum stirring defoaming machine, and subjected to vacuum stirring and defoaming for 7 minutes under the conditions of a revolution speed (rotation of the mixer) of 600 rpm and a self-rotation speed (rotation of the adhesive container) of 500 rpm. The described mixed adhesive was sealed and filled into an encapsulation cavity of an LED (Model 4014) holder by using an adhesive dispenser. The encapsulated LED holder was placed in an automatic centrifuge and centrifuged for 3 minutes at a rotating speed of 1500 rpm. The centrifuged LED holder was baked in an oven at 150° C. for 2 hours.

The CdSe/ZnS green quantum dots were made as follows. First, 1 mmol of cadmium stearate, 50 grams of octadecene (ODE), 2 grams of trioctylphosphine oxide (TOPO), and 2 grams of octadecylamine were heated to 280° C. under a nitrogen atmosphere and then quickly injected into 2 mL of a 0.5 M Se-trioctylphosphine (TOP) solution. The reaction was allowed to proceed for 30 seconds and immediately cooled down to room temperature to purify. Obtained was a small size of CdSe cores with a first exciton absorption peak of about 480 nm. Second, 2 mmol of zinc stearate, 1 gram of oleic acid, 0.05 grams of TOPO, 2.5 grams of octadecylamine, and 10 grams of octadecene were mixed under the nitrogen atmosphere in a flask. The mixture was heated to 300° C. and then 0.2 mmol of the CdSe cores from the previous step and 2 mmol of S-ODE (1M) were injected in sequence. The reaction was carried out for 5 minutes and then cooled down to room temperature. Third, 0.2 mmol of zinc oleate and 0.2 mmol S-ODE solution were added at room temperature. The temperature was raised to 250° C., reacted for 10 minutes, and then reduced to room temperature. The above steps were repeated 5 times to obtain CdSe/ZnS green quantum dots.

Example 2: CdSe/ZnS red quantum dots were used as the red fluorescent material, with an average particle size of from 6 to 40 nm, and a density of 4.9 g/cm³ (which differs from the mass density of the curable resin by 3.75 g/cm³). SrAl₂O₄:Eu²⁺ green phosphor (Dalian Luming Lighting Technology Co., Ltd) was used as the green fluorescent material, with a density of 3.6 g/cm³ (a mass density difference of 2.45 g/cm³ from the curable resin). 80 parts (calculated by weight parts) of thermal curable methyl-phenyl silicone resin with a density of 1.15 g/cm³, 10 parts of red quantum dots, and 10 parts of green phosphor were weighed, mixed evenly and then placed in a vacuum stirring defoaming machine, and subjected to vacuum stirring and defoaming for 7 minutes under the conditions of a revolution speed of 600 rpm and a self-rotation speed of 500 rpm. The described mixed adhesive was sealed and filled into an encapsulation cavity of an LED (the model number is 4014) holder by using an adhesive dispenser. The encapsulated LED holder was placed in an automatic centrifuge and centrifuging for 3 minutes at a rotating speed of 1200 rpm. The centrifuged LED holder was baked in an oven at 150° C. for 2 hours.

The CdSe/ZnS red quantum dots were made as follows. First, 3 mmol of cadmium stearate, 10 grams of octadecene, 2 grams of TOPO and 2 grams of octadecylamine were mixed in a flask under nitrogen atmosphere and heated to 280° C. Then 2 mL of 0.5 M Se-TOP solution was quickly injected into the flask and reacted for 10 minutes. 2 mL of 0.5 M Se-TOP solution was added dropwise at rate of 0.5 mL/h, then cooled down to room temperature to purify. Obtained was a large size of the CdSe cores where the first exciton absorption peak was about 620 nm. Second, 2 mmol of zinc stearate, 1 gram of oleic acid, 0.05 grams of TOPO, 3 grams of octadecylamine, and 20 grams of octadecene were mixed in a flask under nitrogen atmosphere and heated to 300° C. 0.1 mmol (in terms of precursor) CdSe cores from step 1 and 2 mmol of S-ODE (1M) were quickly injected into the flask in sequence, reacted for 5 minutes, and cooled down to room temperature. Third, 0.2 mmol of zinc oleate and 0.2 mmol of S-ODE solution were added at room temperature, the temperature was raised to 250° C., reacted for 10 minutes, and then reduced to room temperature. These steps were repeated 3 times to obtain CdSe/ZnS red quantum dots.

Example 3: K₂SiF₆:Mn⁴⁺ red phosphor was used as the as the red fluorescent material, the density being 3.2 g/cm³. CdSe/ZnS green quantum dots were used as the green fluorescent material, wherein the average particle size of the quantum dots before coating is 15 nm and the density before coating is 4.2 g/cm³, coating SiO₂ by using a sol-gel method, the average particle size after coating SiO₂ is 30 nm±50 nm, and the average density is reduced to 1.4 g/cm³. 60 parts (calculated by weight parts) of thermal curable methyl-phenyl silicone resin with a density of 1.15 g/cm³, 30 parts of red phosphor, and 10 parts of green SiO₂ coated quantum dots were weighed, mixed evenly and then placed in a vacuum stirring defoaming machine, and subjected to vacuum stirring and defoaming for 7 minutes under the conditions of a revolution speed of 600 rpm and a self-rotation speed of 500 rpm. The described mixed adhesive was sealed and filled into an encapsulation cavity of an LED holder by using an adhesive dispenser. The encapsulated LED holder was placed in an automatic centrifugal settling machine and centrifuging for 5 minutes at a rotating speed of 1800 rpm. The centrifuged LED holder was baked in an oven at 150° C. for 2 hours.

The CdSe/ZnS green quantum dots were coated as follows. 200 mg of CdSe/ZnS green quantum dots were dissolved in 100 mL of toluene, then 2 mL of tetramethyl silicate was added, under 60° C., 60% relative humidity conditions, stirred and reacted for 7 days. A transparent gel was obtained, and then dried at 120° C., to obtain the silica-coated green quantum dot material.

FIGS. 2A and 2B are an example cross-sectional view of an LED package prepared by the process of Example 3 and illuminated under blue light, in which the left figure (FIG. 2A) is a control sample that was not centrifuged. It can be observed that the dispersion of the red and green fluorescent materials in the encapsulating adhesive is relatively uniform, and the luminous efficacy is 5.4 lm/W under a current of 20 mA. The right figure (FIG. 2B) is the photo of Example 3, and it can be observed that the red phosphor 220 tends to settle at the bottom of the LED surface (closest to substrate 210) after centrifugation. The green inorganic oxide coated quantum dots 230 do not significantly settle in the encapsulation adhesive, and this optical structure can reduce the energy loss caused by the green light emitted by the quantum dot being absorbed by the red phosphor, Thus, the luminous efficacy can be improved to 5.8 lm/W. The test method related to the following photos: voltage=3V, current=20 mA, lighting test were conducted in an integrating sphere. The test method was a microphotograph of the LED section under blue or UV light.

Example 4: CdSe/ZnS red quantum dots were used as the red fluorescent material with a density of 4.3 g/cm³ before coating, and the average density changed to 4.0 g/cm³ after coating with Al₂O₃ by sol-gel method. The average particle size of red quantum dots after coating with Al₂O₃ was 30 nm to 50 nm. CdSe/ZnS green quantum dots were used as the green fluorescent material, and the density was 4.2 g/cm³ before coating, and the average density was reduced to 1.4 g/cm³ after Al₂O₃ coating by sol-gel method. 80 parts of thermal curable methyl-phenyl silicone resin with density of 1.15 g/cm³, 10 parts of red Al₂O₃-coated quantum dots and 10 parts of green Al₂O₃-coated quantum dots were weighed and mixed evenly in a vacuum stirring and defoaming machine for 7 minutes under the conditions of revolution speed of 600 rpm and self-rotation speed of 500 rpm. The described mixed adhesive was sealed and filled into the encapsulation cavity of LED (model 4014) holder by using an adhesive dispenser. The sealed LED holder was placed in an automatic centrifuge and centrifuged at 1800 rpm for 3 minutes. The centrifuged LED holder was baked in an oven at 150° C. for 2 hours.

The CdSe/ZnS red and green quantum dots were coated with Al₂O₃ as follows. 200 mg of CdSe/ZnS quantum dots were dissolved in 100 mL of toluene and 1 mL of aluminum isopropoxide was added. The reaction was stirred for 7 days at 60° C. and 20% relative humidity to form a gel, and then dried at 120° C., which led to the Al₂O₃-coated red and green quantum dot material.

Example 5: 10 m particle size, 20 nm internal pore size macroporous type ion exchange resin was selected, and 10-15 nm red quantum dots were adsorbed as red fluorescent material. CdSe/ZnS green quantum dots were used as green fluorescent materials. 65 parts of thermal curable methyl-phenyl silicone resin with density of 1.15 g/cm³ (calculated by weight parts), 25 parts of ion exchange resin for red quantum dots and 10 parts of green quantum dots were weighed, mixed evenly and placed in a vacuum stirring and defoaming machine, and subjected to vacuum stirring and defoaming for 7 minutes at revolution speed of 600 rpm and self-rotation speed of 500 rpm. The described mixed adhesive was sealed and filled into the encapsulation cavity of the LED (model 4014) holder by using an adhesive dispenser. The sealed LED holder was placed in an automatic centrifuge and centrifuged at 1500 rpm for 3 minutes. The centrifuged LED holder was baked in an oven at 150° C. for 2 hours.

The method of adsorption of the red fluorescent material in the macroporous ion exchange resin is as follows. 200 mg of 10-15 nm red quantum dots were dissolved in 20 mL of toluene and 800 mg of macroporous ion exchange resin with a particle size of 10 m and an inner pore size of 20 nm was added. After ultrasonication or stirring for 1 hour, the solvent was removed by drying, and then the ion exchange resin with adsorption of red quantum dots was obtained.

Example 6: CdSe/ZnS red quantum dots were used as red fluorescent materials with a density of 4.3 g/cm³. CdSe/ZnS green quantum dots were used as green fluorescent materials with a density of 4.2 g/cm³ before coating, and the average density was reduced to 1.5 g/cm³ after coating with terminal mercaptomethyl methacrylate by ligand exchange method. 50 parts of thermal curable methyl-phenyl silicone resin with density of 1.15 g/cm³, 30 parts of red phosphor and 20 parts of green methyl methacrylate coated quantum dots were weighed and mixed evenly and then placed in a vacuum stirring and defoaming machine and subjected to vacuum stirring and defoaming for 7 minutes under the conditions of a revolution speed of 600 rpm and self-rotation speed of 500 rpm. The described mixed adhesive was sealed and filled into the encapsulation cavity of the LED (model 4014) holder using an adhesive dispenser. The sealed LED holder was placed in an automatic centrifuge and centrifuged at 1200 rpm for 3 minutes. The centrifuged LED holder was baked in an oven for 2 hours at 150° C.

The CdSe/ZnS green quantum dots were coated with the terminal mercaptomethyl methacrylate using ligand exchange as follows. 200 mg of CdSe/ZnS quantum dots were dissolved in 20 mL of toluene and then 1.2 grams of end-sulfhydrylated methacrylate was added. The reaction was stirred at 70° C. for 12 hours. At the end of the reaction, 50 mL of methanol was added to precipitate the reactants, and then centrifugation was performed, and the precipitate was dried at 70° C. Ligand-exchanged green quantum dots with a decrease in the average density to 1.3 g/cm³ were obtained.

Example 7: CdSe/ZnS red quantum dots were used as red fluorescent materials with a density of 4.3 g/cm³. CdSe/ZnS green quantum dots were used as green fluorescent materials and coated with a siloxane having mercaptomethyl or phenyl terminal group (MW=200-600) by ligand exchange method. 80 weight parts of thermal curable methyl-phenyl silicone resin with density of 1.15 g/cm³, 10 parts of red QDs and 10 parts of green siloxane coated QDs were weighed and mixed evenly and then placed in a vacuum stirring and defoaming machine for 7 minutes under the conditions of a revolution speed of 600 rpm and self-rotation speed of 500 rpm. The described mixed adhesive was sealed and filled into the encapsulation cavity of the LED (model 4014) holder by using an adhesive dispenser. The sealed LED holder was placed in an automatic centrifuge and centrifuged at 1800 rpm for 3 minutes. The centrifuged LED holder was baked in an oven for 2 hours at 150° C.

The CdSe/ZnS green quantum dots were coated with the siloxanes having a mercaptomethyl terminal group by ligand exchange as follows. 200 mg of CdSe/ZnS quantum dots were dissolved in 20 mL of toluene and then 1.8 grams of end-mercapturized siloxane was added. The reaction was stirred at 70° C. for 12 hours. At the end of the reaction, 5 mL of methanol was added, and the precipitate was dried at 70° C. after centrifugation to obtain the ligand-exchanged green quantum dots.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method for making a layered structure, the method comprising:
mixing a red fluorescent material and a green fluorescent material with a curable resin to produce an adhesive mixture;
dispensing the adhesive mixture onto a substrate;
centrifuging the adhesive mixture such that the red fluorescent material and the green fluorescent material separate to form a layered structure; and
curing the layered structure onto the substrate.

2. The method of claim 1, wherein the red fluorescent material is a phosphor or a quantum dot and the green fluorescent material is a phosphor or a quantum dot.

3. The method of claim 1, wherein the curable resin is a methyl-phenyl silicone resin.

4. The method of claim 1, wherein centrifuging comprises:
centrifuging the adhesive mixture to form a centrifuged adhesive mixture;
partially curing the centrifuged adhesive mixture to form a partially cured centrifuged adhesive mixture; and
inverting the partially cured centrifuged adhesive mixture.

5. The method of claim 1, wherein the red fluorescent material has a larger particle size than the green fluorescent material.

6. The method of claim 1, wherein a density of the red fluorescent material minus a density of the curable resin is greater than a density of the green fluorescent material minus the density of the curable resin.

7. The method of claim 1, further comprising, prior to mixing, modifying the red fluorescent material with a modifying material.

8. The method of claim 7, wherein the modifying material comprises an alkynyl and an azide group or a transcyclooctenyl and a tetrazine group.

9. The method of claim 7, wherein the modifying material comprises a silane coupling agent that reacts with an inorganic oxide particle by condensation.

10. The method of claim 7, wherein the modifying material comprises an inorganic oxide.

11. The method of claim 1, further comprising, prior to mixing, coating the green fluorescent material with a coating material.

12. The method of claim 11, wherein the coating material comprises an inorganic oxide or a polymer.

13. The method of claim 1, further comprising, prior to mixing, modifying the green fluorescent material with a modifying material.

14. The method of claim 13, wherein the modifying material comprises a silane.

15. The method of claim 1, wherein centrifuging is conducted at a temperature in a range of 50 to 120° C.

16. The method of claim 1, wherein centrifuging is conducted at a temperature in a range of −20 to 5° C.

17. The method of claim 1, wherein the red fluorescent material is in a carrier material.

18. The method of claim 17, wherein the carrier material is a mesoporous material selected from the group consisting of an ion exchange resin, SiO₂, TiO₂, ZrO₂, Al₂O₃, ZnO, ZnMgO, SnO₂, and combinations thereof.

19. The method of claim 1, wherein the adhesive mixture further comprises additives, wherein the additives are selected from the group consisting of solvents, oligosilanes, thickeners, fumed silica particles, and combinations thereof.

20. A method for making a layered structure, the method comprising:
mixing a red fluorescent material and a green fluorescent material with a curable resin to produce an adhesive mixture;
dispensing the adhesive mixture onto a substrate;
phase separating the adhesive mixture such that the red fluorescent material and green fluorescent material separate to form a layered structure; and
curing the layered structure onto the substrate.
